(19) United States
(12) Patent Application Publication
(10) Pub. No.: US 2007/0153889 A1
(43) Pub. Date: Jul. 5, 2007

(54) Application of leakage to an adaptive equalizer

(76) Inventor: David E. Norton JR., Boulder, CO (US)

Correspondence Address: MORRISON & FOERSTER LLP, 755 PAGE MILL RD, PALO ALTO, CA, 94304-1018, US

(21) Appl. No.: 11/325,895

(22) Filed: Jan. 4, 2006

(51) Int. Cl. H03K 5/159; H04B 1/10

(52) U.S. Cl. 375/232; 375/350

(57) ABSTRACT

Digital signal processing apparatus and methods for modifying frequency response of a signal is described herein. In one aspect, the invention relates to an improved method for stabilizing the LMS adaptation of an FIR filter. In another aspect, the invention relates to a digital equalizer with tap weights that are adapted to move towards some pre-defined tap weight reference, rather than towards zero. In one variation, the digital equalizer is able to provide both signal equalization and automatic gain control.

### FIELD OF THE INVENTION

The invention is related generally to the field of signal processing. In one aspect of the invention, apparatus and methods disclosed herein can be implemented for improving the performance of adaptive equalizers.

### BACKGROUND

Various digital signal processing schemes have been developed over the years to improve detection of data encoded in analog signal streams. In particular, equalizers are provided to process the digital signals which are converted from the analog signals. The equalizers can improve signal to noise ratio and enhance the systems' ability to detect data embedded in the analog signals.

A common problem related to reading data from an analog signal stream arises in reading digital data stored in a physical medium. Typically a transducer is used to detect the data encoded in the storage medium. The transducer generates an analog electrical signal representing the data. The analog signal is then converted to a digital signal through an analog to digital converter. A digital filter, such as an equalizer, is then utilized to remove noise and other signal artifacts before a detector (e.g., Viterbi detector) is used to extract the data encoded in the digital signal. An example of such a design is shown in U.S. Pat. No. 6,249,398 B1, entitled “Class of Fixed Partial Response Targets in a PRML Sampled Data Detection Channel”, issued to Fisher et al., dated Jun. 19, 2001. Since noise can be introduced by both the medium itself and the detection process, the performance of the digital filter can be important in removing the noise and improving the performance of the over all system.

For example, in a data storage tape drive the head/tape interface typically has a significant amount of variation over the population of tapes that a given drive sees over its service life. This variation is a result of multiple factors including, but not limited to, surface roughness, coating thickness, head wear, head parametrics, etc. This variation can manifest itself as uncertainty in both the output amplitude and frequency content. In modern read channel design, this issue is addressed by the inclusion of an adaptive equalizer and automatic gain control (AGC), as the parameters that affect the channel response vary within the length of a single tape. This adaptive equalizer is most often driven using a least mean square (LMS) algorithm that attempts to minimize error in the equalized output.

Traditionally an equalizer having some number of taps is combined with an AGC, with the equalizer serving to adapt the frequency response, and the AGC for adapting the amplitude. However, there is a potential complication with this topology: in the equalizer, if all taps are allowed to update, the gain of the equalizer will affect the gain of the AGC, and vice versa. Therefore, when all the taps in the equalizer are allowed to update, the operation of the equalizer is not independent of the operation of the AGC. This interaction may result in a situation where the gain of one moves high, while the other moves low, resulting in either high noise or saturation in the circuits if the final gain is set low. This has led to the practice of fixing some number of the taps in the equalizer. As a result of fixing one or more of the taps, the equalizer cannot accurately control the gain forcing the gain control action into the AGC. In addition, fixing of a specific number taps would lead to constraints in the possible number of solutions in the equalizer, and therefore degrade the performance of the equalizer.

Another potential complication associated with a traditional LMS adaptive equalizer is that the time position of the response is not fixed. This has the ramification that the response may drift about the equalizer until the main portion of the response hits one of the ends (since this is a digital circuit, the output is bounded by the number bits supported by the circuit), at which point the error from the LMS adaptation increases, constraining the response. Again what is typically done to correct this problem is to fix some number of taps, most often a pair of adjacent taps with a large difference, so that the error increases rapidly if the adaptation tries to diverge from this position. This, of course, has the result of constraining the possible number of solutions in the equalizer, so the filter will likely operate in a somewhat degraded fashion from what otherwise would be possible.

A third complication can arise in the presence of a dropout, where there is no information being provided to the LMS adaptive equalizer. Under this condition, the tap weights will drift, possibly tuning into a response from which it cannot return, forcing a recovery action, which can vary from invoking the error correction code (ECC) to executing a back hitch, resetting the equalizer response, and reading the data again. Furthermore, the adapter can also drift when the input to the LMS term is incoherent (i.e., there is not systematic feedback present).

Therefore, there is a need for an LMS adaptive equalizer with improved system stability and performance. In particular, the ability to prevent drifting of the adaptive filter can be desirable. In addition, it may also be desirable in certain applications to provide an equalizer with built-in AGC capability.

### SUMMARY OF THE INVENTION

Disclosed herein are signal processing apparatuses and methods for improving the detection of encoded data in an analog signal stream. In one variation, the signal processing apparatus comprises an analog to digital converter and a digital equalizer configured to process the digital signal from the analog to digital converter. The digital equalizer includes a finite input response filter having a response profile modifiable by a series of tap weights, each of the tap weights in the series is determined by varying a tap weight reference by a feedback based on an output of the digital equalizer and an estimate of the output. In one variation, the feedback is provided by a least means square comparator comparing the output of the digital equalizer and the estimate of the output. A maximum likelihood detector is connected to the output of the digital equalizer. The maximum likelihood detector processes signal provided by the digital equalizer and outputs the data. The maximum likelihood detector also generates an estimate of the digital equalizer output, which is fed back to the digital equalizer. In one application, the digital equalizer is configured with a plurality of taps and each of the tap weights are adapted to return to a corresponding tap weight reference when the input to the digital equalizer is absent, or when there is no systematic feedback present for the finite input response filter. The tap weight reference may be provided as a vector with multiple elements, where each of the elements represents a tap weight reference value for a corresponding tap in the digital equalizer. In addition, the digital equalizer may be adapted to provide automatic gain control.

In one example, the digital equalizer comprises a plurality of delay elements, a plurality of multipliers, which are coupled to the delay elements, a summation block connected to the plurality of multipliers, a least means square comparator, which compares the output of the summation block with an estimated output and generates an error signal, and a tap weight engine which receives the error and calculates tap weights. The tap weights are applied to the multipliers. The tap weight engine calculates each of the tap weights in relation to a tap weight reference which is a constant value. The tap weight reference is scaled by a gain term that controls the rate at which the tap weights calculated by the tap weight engine returns to the tap weight reference when an input to the digital equalizer is absent or when there is no systematic feedback present for the finite input response filter. In one variation, the digital filter is implemented on an integrated circuit.

In another aspect, methods of determining tap weights for a least means square adaptive equalizer are disclosed herein. In one variation, the method comprises receiving an analog signal and converting the analog signal to a digital signal. A series of tap weights is calculated based on a least means square calculation, which is offset by a tap weight reference. The digital signal is then modulated by a finite input response filter weighted according to the series of tap weights. A maximum likelihood detector is then used to detect data in the signal that has been processed by the finite input response filter. The maximum likelihood detector also calculates an estimated value of the finite input response filter output, which is utilized in the least means square calculation for determining the series of tap weights. In one variation, the tap weights are adapted such that the finite input response filter also provides automatic gain control.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 illustrates one variation of a signal processing apparatus with an LMS adaptive digital equalizer. The signal processing apparatus comprises an A/D converter, an LMS adaptive digital equalizer, and a maximum likelihood detector.

FIG. 2 is a diagram illustrating one variation of an LMS adaptive digital equalizer.

FIG. 3 illustrates an example where the LMS adaptive digital equalizer with modified leakage is implemented in a data storage tape drive.

FIG. 4 is an example plot of a traditional LMS adaptive equalizer's tap gains as the tap gains change in time. As shown, the equalizer is unstable and the taps are drifting. The horizontal scale is the bit number; the vertical scale is the tap gain.

FIG. 5A is an example plot of an improved LMS adaptive equalizer's tap gain as they change in time. The position of the taps stabilizes in time.

FIG. 5B is an expanded view of the beginning region of the plot in FIG. 5A. As shown in FIG. 5B, in the beginning region, the taps move together, similar to the characteristics of a fixed filter with its gain being adjusted.

FIG. 6 is a flow chart illustrating an exemplary method for determining tap weights for an LMS adaptive equalizer.

### DETAILED DESCRIPTION OF THE INVENTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

Magnetic data storage tape drive is used herein as an example application of the LMS adaptive equalizer, in order to illustrate the various aspects of the invention disclosed herein. In light of the disclosure herein, one of ordinary skill in the art would appreciate that the methods and apparatuses disclosed herein can be implemented in various other apparatus or systems for signal processing and decoding of data embedded in a signal.

It must also be noted that, as used in this specification and the appended claims, the singular forms “a,” “an” and “the” include plural referents unless the context clearly dictates otherwise. Thus, for example, the term “a read head” is intended to mean a single read head or a combination of read heads, “an electrical signal” is intended to mean one or more electrical signals, or a modulation thereof.

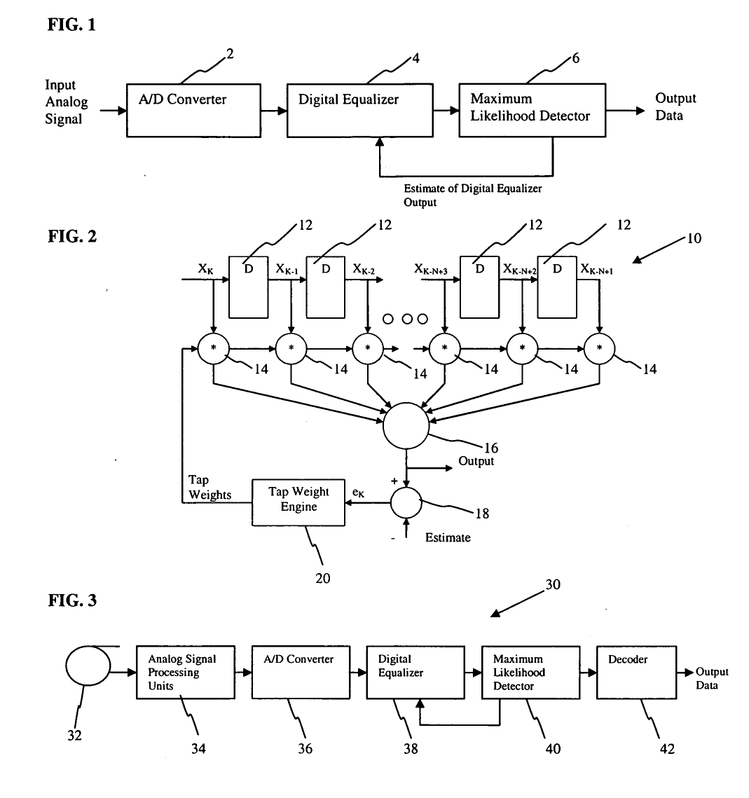

Referring to FIG. 1, an example of the signal processing apparatus is illustrated. An analog signal with encoded data is input into the Analog to Digital (A/D) converter 2. The output of the A/D converter 2 is transmitted to the digital equalizer 4. The equalized digital signal is directed to the maximum likelihood detector 6 (e.g., Viterbi detector). The maximum likelihood detector 6 detects the binary data encoded in the digital signal stream. The maximum likelihood detector 6 also generates an estimate of the digital equalizer output, which is fed back into the digital equalizer 4.

The digital equalizer 4 is implemented as a finite input response filter (FIR) 10 with LMS feedback, as shown in FIG. 2. The LMS algorithm provides adaptive feedback so that the response of the FIR filter may adapt to the changes in system response (e.g., head/media changes). The filter 10 comprises a plurality of delay elements 12, a plurality of multipliers 14, which are coupled to the delay elements 12, and a summation block 16 connected to the plurality of multipliers 14. A least means square comparator 18 which compares the output of the summation block 16 with an estimated output, generates an error signal “e”. One of ordinary skill in the art having the benefit of this disclosure would appreciate that other comparators may also be implemented to generate the error signal. The tap weight engine 20 receives the error signal and calculates new tap weights, which are adapted to minimize the error. The tap weights are applied to the multipliers 14.

The tap weight engine 20 calculates the tap weights according to the following equation:
TWₖ₊₁=(1−μₗₑₐₖ)·(TWₖ−μₗₘₛ·eₖ·Xₖ)+μₗₑₐₖ·TWR (1)

TW is the tap weight vector. μₗₘₛ is a least means square gain term. e is an error term defined as a difference between the output of the summation block and the estimated output. X is the vector representing the input values to the digital filter. TWR is the tap weight reference vector. μₗₑₐₖ is a gain term for the TWR. μₗₑₐₖ controls the rate at which, absent any input to the contrary, the tap weight returns to the reference value defined by TWR. k is a time index. As shown in Equation (1), the tap weight engine calculates each of the tap weights in relation to a tap weight reference, TWR. In this example, TWR is a constant value.

In one variation, μₗₑₐₖ is a value much less than one, and additionally it is less than μₗₘₛ, which implies that in normal operation the action of the root LMS equation as defined by μₗₘₛ is dominant. However, in situations where the error term reverts to noise, such as in a dropout, the μₗₑₐₖ term will take over, returning the system to the reference tap values. This also has the advantage of pinning the tap weights in time, as a significant divergence from the reference values will result in significant error, constraining the taps to be close to their initial positions.

To explain the dynamics of this improved digital equalizer, a useful analogy is that each tap (i.e., TW) has a small spring drawing it back toward its reference (i.e., TWR). If the excitation from the LMS is strong, then it will overcome the spring, but when it is weak the leakage term will dominate, returning the response to the prototype filter response, which is defined by the tap weight reference. This design may have one or more of the following advantages: (1) if the LMS has no input, the tap weight returns to its prototype, therefore for those frequency ranges where no information exists, the prototype response dominates; (2) if the response tries to shift in time, all of the springs will deflect, so the force holding the response in place in time is the number of taps times the individual leakage; (3) gain changes involve all taps, requiring a large change from the prototype response which is resisted by the combination of al the springs, so this would correct the issue of interaction between the LMS and AGC. When the LMS equalizer is architected correctly, it can provide additional AGC function, and a separate AGC may not be needed. The apparatus returns to the prototype response if the SNR becomes poor, such as the input to the digital equalizer is absent (e.g., in a dropout), or when there is no systematic feedback present for the finite input response filter (e.g., the data encoding frequency content does not fully drive the LMS). In a situation where the SNR is low, a traditional system may drift about on noise. The above design forces the tap weights towards the reference tap weights and thereby maintains system stability.

In one application, the tap weight reference is provided in an a priori fashion, where an appropriate equalizer has been determined in the lab, and is applied as a starting point, from which the LMS is allowed to adapt during a calibration process while manufacturing the product. The results of this calibration are then written back into a memory on the product, and used as a starting point (i.e., prototype) for subsequent operation. In one variation, the system is calibrated to determine the starting tap weights. The starting tap weights are then utilized both as the tap weight reference and as the initial tap weights supply to the taps in the equalizer at system initiation. In this variation, the tap weights of the equalizer start at the reference tap weights and then moves about the reference tap weights as the equalizer adapts to the input signal. In another variation, the tap weight reference utilizes a separate set of values from the starting tap weights, which are utilized to initialize the taps in the equalizer.

To define the appropriate starting tap weights and/or tap weight reference, a couple of methodologies can be utilized. In the first example, one would execute a “random walk”, where a search of the tap weights is made, and the quality of operation mapped. Alternatively, a characterization process may be undertaken, where a known data pattern is written, and the input of the equalizer is sampled. These samples are then de-convolved with the original written information, and a transfer function calculated. This channel transfer function may then be de-convolved with the desired detection transfer function (as specified by the Viterbi detector), resulting in the form of the equalizer (i.e. tap weights).

In one variation, the constants (i.e., μₗₑₐₖ, μₗₘₛ, and TWR) in Equation (1) are pre-selected such that the equalizer provides AGC on the input signal in addition to the equalizer functionality. The gains associated with the system as an AGC or as an adaptive equalizer are a function of normal feed-back control theory. One of ordinary skill in the art having the benefit of this disclosure would be able to select the appropriate gains to meet the needs of specific design requirement based on the overall system design. The gains selected can be a function of the noise present (both in magnitude and frequency content), and trade-offs can be made between noise rejection, system stability, and acquisition speed, depending on specific application needs.

It should be noted that an LMS adaptive equalizer can function as an AGC when all taps are allowed to update. Many of the LMS adaptive equalizer in the market has one or more fixed taps and therefore cannot provide AGC, since all taps need to change in order to alter just the gain. By utilizing Equation (1) and allowing all the taps to update, the filter functions as an equalizer and an automatic gain controller. The techniques described herein provide system stability while at the same time allows all taps to be updated, therefore freeing the LMS equalizer to control the gain also. This design may allow the separate AGC, which is conventionally provided after the equalizer for gain control, be removed.

One of ordinary skill in the art having the benefit of this disclosure would appreciate that the LMS adaptive digital equalizer disclosed herein can be implemented in various components or systems which require the extraction of data encoded in an analog signal stream. For example, the digital equalizer can be implemented in a data storage magnetic tape drive 30 as shown in FIG. 3. A magneto-resistive tape drive head 32 (i.e., transducer) reads the data written on a magnetic tap (i.e., data storage medium). The magneto-resistive tape drive head 32 generates an analog signal that is transmitted through one or more analog signal processing units 34 (e.g., analog filters, analog AGC, etc.). The A/D converter 36 receives the analog signal and converts it into a digital signal stream. The digital signal stream is processed by the LMS adaptive equalizer 38, and then sent to the maximum likely hood detector 40. The detected bits are input to a decoder 42, which reconstruct the original user data from the modulation encoded form. The LMS adaptive equalizer disclosed herein can also be utilized in data storage drives that are configured for reading data from various other data storage mediums (e.g., hard drive, CD, CDR, CD-RW, DVD, DVD-R, DVD-RW, etc.). In addition, the LMS adaptive equalizer can also be implemented in network receivers, such as routers, cable modems, or cell phones. Furthermore, one of ordinary skill in the art having the benefit of this disclosure would appreciate that, where appropriate, the LMS equalizer can be implemented in hardware, software, firmware of a combination thereof.

An example is provided below to illustrate the difference between the present LMS adaptive equalizer as compared to a traditional LMS adaptive equalizer. As discussed earlier in one variation, the improved LMS adaptive equalizer disclosed herein utilizes the following equation to update the tap weights:
TWₖ₊₁=(1−μₗₑₐₖ)·(TWₖ−μₗₘₛ·eₖ·Xₖ)+μₗₑₐₖ·TWR (1)

The central part of the equation is similar to a traditional LMS adaptive equalizer. The equation further includes two gain terms: μₗₘₛ for the LMS gain, and μₗₑₐₖ as a leakage gain. There is also the tap weight reference vector TWR. In the absence of significant input from the LMS term the equalizer will move toward the reference, TWR.

Note that if the leakage gain, μₗₑₐₖ, is set to zero, Equation (1) defaults to a traditional LMS:
TWₖ₊₁=(TWₖ−μₗₘₛ·eₖ·Xₖ) (2)

In Equation (2), TW is a vector of tap weight values; μₗₘₛ is a gain term that controls the bandwidth of the adaptation; e is the error present in the current sample where error is defined as the difference between the actual sample value and the estimated value; and X is the vector of filter input values from which this error was derived. This equation distributes the error across the taps such that the error is apportioned based on the amplitude present on that tap when that error was calculated. In comparison, Equation (1) maintains this aspect of the LMS, which is to say that it is still based on minimizing the error.

To demonstrate the performance of the improved LMS adaptive equalizer disclosed herein, the equalizer is modeled on a computer. In the first demonstration, μₗₑₐₖ is set to zero, so the equalizer function like a traditional LMS equalizer with tap weights defined by Equation (2). For this demonstration, μₗₘₛ is set to 2⁻⁶, and the tap values on the equalizing filter are initialized as:

$$Taps = ( \begin{matrix}0 \\ 0 \\ - 32 \\ 77 \\ 71 \\ - 32\end{matrix} )$$

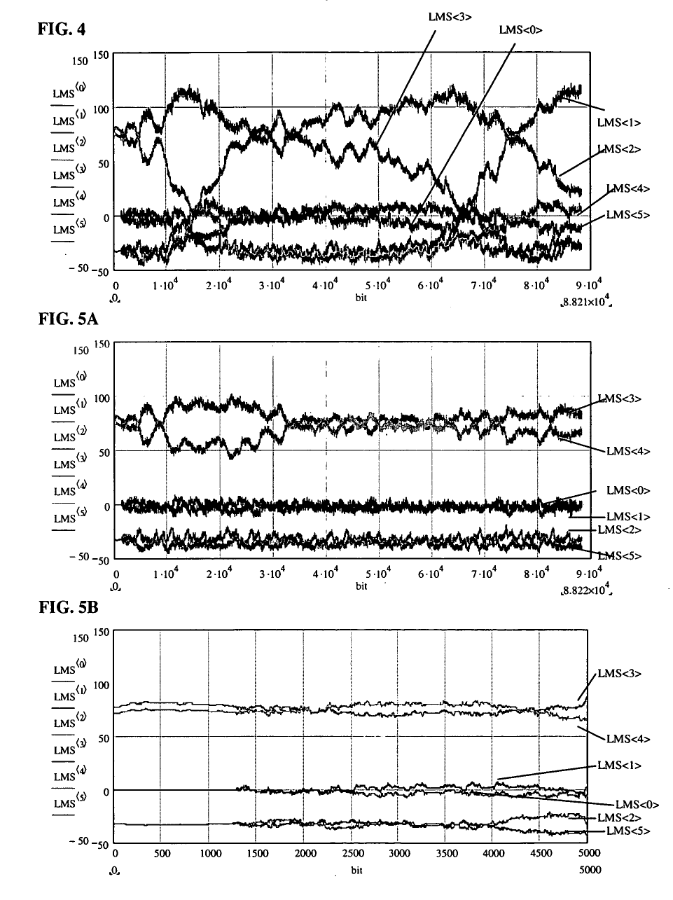

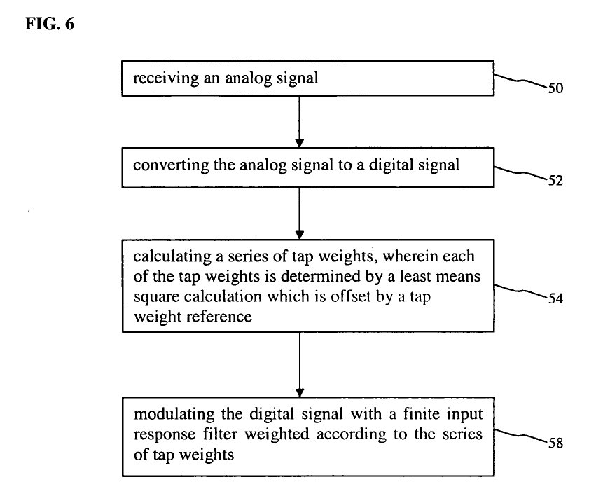

Note that there are a couple of leading zeros in this vector. This was done so that the filter would have a range to drift into. FIG. 4 is a plot of the equalizer tap weights as the LMS is allowed to adapt the filter over a data set captured on a tape drive using digital sampling oscilloscope. The horizontal scale is the bit number, the vertical scale is the tap gain. Note that this system is not stable and the taps are drifting.

In the second demonstration, μₗₑₐₖ is set to 2⁻¹⁴ instead of zero. As a result, the tap weights in the equalizer are updated by Equation (1). Note, this number, 2⁻¹⁴, is less than one, and it is also less than μₗₘₛ, which is set to 2⁻⁶. In this demonstration the tap weight reference is set to the same values as the initial tap weights.

$$TWR = ( \begin{matrix}0 \\ 0 \\ - 32 \\ 77 \\ 71 \\ - 32\end{matrix} )$$

The initial tap weight vector and the tap weight reference vector can be the same, such as in this demonstration, but need not be the same. As shown in FIG. 5A, the position of the taps stabilizes in time. There is also a significant improvement in noise performance; the SNR (Signal to Noise Ratio) of this demonstration is 22.9 dB (based on peak target to RMS noise), versus 22.4 dB in the previous demonstration (i.e., a 0.5 dB improvement).

Close examination of the plot in FIG. 5A shows that there is a different characteristic present at the beginning of the plot. In this beginning region, the circuit is in the AGC mode. FIG. 5B is an expanded view of this beginning region. As shown in FIG. 5B, in the AGC mode, the taps move together, indicating that the gain of a fixed filter is being adjusted. At about 1300 bits, the system has detected lock and moved to the frequency adaptation mode. It should be noted that operation in this region is somewhat noisier than would normally be encountered. The gain in this example is set high so as to exaggerate the drifting phenomena.

As shown in the above demonstration, the improved LMS equalizer can be adapted to provide both AGC functionality and equalizer functionality. The equalizer first function in AGC mode then shift into an LMS adapter mode. The reason for this mode shift is that during the initial lockup of the channel timing and amplitude errors are frequently present. These errors are a significant source of noise to the LMS. The system will work to a lower signal to noise ratio (SNR) if timing and gain errors are adapted before the attempt is made to adapt the equalizer. Therefore, the adapter moves into a mode to correct the amplitude as the PLL (Phase Lock Loop) is correcting the phase, and the complexities of a varying frequency response are not introduced. Once the amplitude and phase are adapted, the system moves into the LMS adaptation mode, and the equalizer response is adjusted.

In another variation, the LMS adaptation is modified such that the LMS adapted FIR filter can operate as just an AGC. This configuration is represented by the following equation:
TWₖ₊₁=TWₖ·(1−μ_{agc}·eₖ·sign(exp)) (3)

Note that μ_{agc} is the gain constant that defines the band width in the AGC mode, and exp is the expected value (e.g., an estimate of the output provided by the maximum likelihood detector). In operation, this equation functions to modulate the gain of the signal. In addition, the error is not distributed across the taps, such that the gain of all the taps is changed by the same amount.

As discussed above, one aspect of this invention includes methods of updating tap weights as illustrated in the processes implemented by the above devices. FIG. 5 illustrates one of the exemplary methods in a flow chart. The method comprises receiving an analog signal having an encoded user data 50; converting the analog signal to a digital signal 52; calculating a series of tap weights, wherein each of the tap weight is determined by a least means square calculation which is offset by a tap weight reference 56; and modulating the digital signal with a finite input response filter weighted according to the series of tap weights 58. In one variation, automatic gain control is applied on the digital signal with the finite input response filter while modulating the digital signal. The tap weight can be determined by Equation (1). In another variation, the method further includes calculating the estimated value of the output with a maximum likelihood detector. The estimated value can then be use by the least mean square calculation to determine an error for the calculation of the tap weights.

This invention has been described and specific examples of the invention have been portrayed. While the invention has been described in terms of particular variations and illustrative figures, those of ordinary skill in the art will recognize that the invention is not limited to the variations or figures described. In addition, where methods and steps described above indicate certain events occurring in certain order, those of ordinary skill in the art will recognize that the ordering of certain steps may be modified and that such modifications are in accordance with the variations of the invention. Additionally, certain of the steps may be performed concurrently in a parallel process when possible, as well as performed sequentially as described above. Therefore, to the extent there are variations of the invention, which are within the spirit of the disclosure or equivalent to the inventions found in the claims, it is the intent that this patent will cover those variations as well. Finally, all publications and patent applications cited in this specification are herein incorporated by reference in their entirety as if each individual publication or patent application were specifically and individually put forth herein.

What is claimed is:

1. A signal processing apparatus comprising:
a digital filter having a response profile modifiable by a plurality of tap weights; and
a feedback logic for modifying the tap weights as a function of at least one tap weight reference and a feedback based on an output of the digital filter and an estimate of the output.

2. The signal processing apparatus according to claim 1, wherein the series of tap weights is determined by:
TWₖ+1 is a function of (1−μₗₑₐₖ)·(TWₖ−μₗₘₛ·eₖ·Xₖ)+μₗₑₐₖ·TWR
wherein TW is the tap weight, μₗₘₛ is a least means square gain term, e is an error term defined as a least means square difference between the output of the digital filter and an estimate of the output, X is an input to the digital filter, TWR is the tap weight reference, μₗₑₐₖ is a gain term for the TWR, and k is a time index.

3. The signal processing apparatus according to claim 2, wherein the digital filter comprises a finite input response filter, and μₗₑₐₖ is determines a rate at which each tap weight returns to its corresponding tap weight reference when the input to the finite input response filter is absent.

4. The signal processing apparatus according to claim 3, wherein μₗₑₐₖ is determines the rate at which the tap weights return to TWR when there is no systematic feedback present for the finite input response filter.

5. The signal processing apparatus according to claim 4, further comprising:
a maximum likelihood detector connected to the digital filter, wherein the estimate of the output is provided by the maximum likelihood detector.

6. The signal processing apparatus according to claim 5, wherein the tap weight reference is a constant determined by a frequency response of a system in which the digital signal processing apparatus is implemented.

7. The signal processing apparatus according to claim 2, further comprising:
a maximum likelihood detector connected to the digital filter, wherein the estimate of the output is provided by the maximum likelihood detector.

8. The signal processing apparatus according to claim 7, wherein the maximum likelihood detector comprises a Viterbi detector.

9. The signal processing apparatus according to claim 1, wherein the tap weight reference is a constant selected based on a frequency response of a system in which the digital signal processing apparatus is implemented.

10. The signal processing apparatus according to claim 1, wherein the tap weight reference is a default tap weight value that the tap weight converges to when an input to the digital filter is absent or when there is no systematic feedback to the digital filter.

11. The signal processing apparatus according to claim 1, wherein the digital filter is operable to provide automatic gain control.

12. The signal processing apparatus according to claim 2, wherein the digital filter is implemented on an integrated circuit.

13. A digital filter comprising:
a plurality of delay elements;
a plurality of multipliers coupled to the delay elements, wherein each multiplier has an input for receiving a tap weight;
a summation block connected to the plurality of multipliers;
a comparator for comparing the output of the summation block with an estimated output, and generating an error signal; and
a tap weight engine for computing the tap weights based upon the error signal and a tap weight reference, wherein the tap weight reference has a constant value.

14. The digital filter according to claim 13, wherein the tap weight reference is scaled by a gain term that controls the rate at which the tap weights calculated by the tap weight engine returns to the tap weight reference when an input to the digital filter is absent, and the comparator comprises a least means square comparator.

15. The digital filter according to claim 13, wherein the tap weight engine calculates each of the tap weights according to:
TWₖ₊₁=(1−μₗₑₐₖ)·(TWₖμₗₘₛ·eₖ·Xₖ)+μₗₑₐₖ·TWR
wherein TW is the tap weight, μₗₘₛ is a least means square gain term, e is an error term defined as a difference between the output of the summation block and the estimated output, and X is an input to the digital filter, TWR is the tap weight reference, and μₗₑₐₖ is a gain term for the TWR, and k is a time index.

16. The filter according to claim 15, wherein μₗₑₐₖ is selected to control a rate at which the tap weight return to TWR when the input to the digital equalizer is absent or when there is no systematic feedback present for the finite input response filter.

17. The digital filter according to claim 16, wherein the digital equalizer is operable to provide automatic gain control.

18. The digital filter according to claim 17, wherein the digital filter is implemented on an integrated circuit.

19. The digital filter according to claim 13, wherein the tap weight engine calculates each of the tap weights by distributing error across the tap weights based on how large an input was when the error was calculated.

20. The digital filter according to claim 13, wherein the digital equalizer is operable to provide automatic gain control.

21. A digital filter comprising:
a adaptive equalizer, wherein tap weights for the adaptive equalizer are adapted based on
TWₖ₊₁=(1−μₗₑₐₖ)·(TWₖ−μₗₘₛ·eₖ·Xₖ)+μₗₑₐₖ·TWR
wherein TW is a vector of tap weight values, μₗₘₛ is a least means square gain term, e is an error term defined as a difference between an output of the adaptive equalizer and an estimate of the adaptive equalizer output, and X is an input to the adaptive equalizer, TWR is a vector of tap weight reference values, and μₗₑₐₖ is a gain term for the TWR, and k is a time index.

22. The digital filter according to claim 21, further comprising:
an analog to digital converter connected to the adaptive equalizer to provide the input to the adaptive equalizer; and
a maximum likelihood detector connected to the adaptive equalizer, wherein the estimate of the adaptive equalizer output is provided by the maximum likelihood detector.

23. The digital filter according to claim 22, wherein the digital filter is implemented on an integrated circuit.

24. The digital filter according to claim 23, wherein μₗₑₐₖ is selected to control a rate at which the tap weight return to TWR when the input to the digital equalizer is absent.

25. The digital filter according to claim 24, wherein the digital equalizer is operable to provide automatic gain control.

26. The digital filter according to claim 25, wherein the digital filter is implemented on an integrated circuit.

27. A method of determining tap weights for a least means square adaptive equalizer, the method comprises:
receiving an analog signal;
converting the analog signal to a digital signal;
calculating a series of tap weights, wherein each of the tap weight is determined by an error calculation and offset by a tap weight reference; and
modulating the digital signal with a filter weighted according to the series of tap weights.

28. The method according to claim 27, wherein each of the tap weights is determined by:
TWₖ₊₁=(1−μₗₑₐₖ)·(TWₖ−μₗₘₛ·eₖ·Xₖ)+μₗₑₐₖ·TWR
wherein TW is the tap weight, Slims is a least means square gain term, e is an error term defined as a least means square difference between an output of the filter and an estimated value of the output, and X is an input to the filter, TWR is the tap weight reference, and μₗₑₐₖ is a gain term for the TWR, and k is a time index, and the filter comprises a finite input response filter.

29. The method according to claim 27, wherein modulating the digital signal further comprises applying automatic gain control on the digital signal with the filter.

30. The method according to claim 29, wherein each of the tap weights is determined by:
TWₖ₊₁=(1−μₗₑₐₖ)·(TWₖ−μₗₘₛeₖXₖ)+μₗₑₐₖ·TWR
wherein TW is the tap weight, μₗₘₛ is a least means square gain term, e is an error term defined as a least means square difference between an output of the finite input response filter and an estimated value of the output, and X is an input to the finite input response filter, TWR is the tap weight reference, and μₗₑₐₖ is a gain term for the TWR, and k is a time index.

31. The method according to claim 30, further comprising:
calculating the estimated value of the output with a maximum likelihood detector.

32. A digital signal processor operable to perform the method according to claim 31.
